(19) United States
(12) Patent Application Publication
(10) Pub. No.: US 2024/0363363 A1
(43) Pub. Date: Oct. 31, 2024

(54) METHOD OF MANUFACTURING SEMICONDUCTOR WAFER AND SEMICONDUCTOR DEVICE

(71) Applicant: GLOBALWAFERS JAPAN CO., LTD., Kitakanbara-gun (JP)

(72) Inventors: Ken HAYAKAWA, Kitakanbara-gun (JP); Haruo SUDO, Kitakanbara-gun (JP)

(73) Assignee: GLOBALWAFERS JAPAN CO., LTD., Kitakanbara-gun (JP)

(21) Appl. No.: 18/632,742

(22) Filed: Apr. 11, 2024

(30) Foreign Application Priority Data
Apr. 27, 2023 (JP) 2023-073006

(51) Int. Cl. H01L 21/324

(52) U.S. Cl. CPC H01L 21/324

(57) ABSTRACT

A method of manufacturing semiconductor wafers comprises the RTA process, wherein a wafer is placed on a wafer support member having a support surface inclined downwardly toward the inside, the RTA process is performed, and further wherein an angle between the wafer backside and the wafer backside bevel is formed at an obtuse angle, and the semiconductor wafer is processed so that the top of the obtuse angle contacts the support surface during the RTA process. During the RTA process, the angle θ1 of the angle between the wafer backside and the support surface and the angle θ2 of the angle between the backside bevel and the support surface formed at the contact position with the support surface are θ1≥5° and θ2≥5°, respectively, and the difference between the angles θ1 and θ2 is |θ1−θ2|≤5°, whereby the semiconductor wafer is produced.

### TECHNICAL FIELD

The present invention relates to a method of manufacturing semiconductor wafers including a step of performing the rapid thermal annealing (RTA) process.

### BACKGROUND ART

A large number of grown-in defects exist on the surface and in the surface layer of a semiconductor wafer, which is obtained by slicing a semiconductor single crystal ingot grown by the Czochralski (CZ) method. Meanwhile, since semiconductor wafers are required to be almost defect-free on the surface and in the surface layer, the RTA process is conventionally performed, which is one of the methods to eliminate the defects on the surface and in the surface layer.

The heat treatment of rapid heating and the rapid cooling by the RTA process eliminates the defects on the surface and in the surface layer of semiconductor wafers and further, densely forms bulk micro-defects (BMD) in the bulk region. The BMD in the bulk region diffuses during the semiconductor device fabrication process and acts as a gettering site for metal impurities that can affect the characteristics of devices.

For example, as a method of manufacturing silicon wafers including the step of performing the RTA process, the patent literature 1 listed below discloses a method of forming BMD highly densely at the time of precipitation heat treatment thereafter, by subjecting the silicon wafer to the RTA process at a temperature of not less than 1300° C. and not more than 1400° C. in an oxidizing atmosphere and by leaving a large amount of vacancies, point defects, in the bulk region of the silicon wafer.

As a pre-preprocess for performing the heat treatment by RTA, for example, Patent Literature 2 and 3 listed below disclose that silicon wafers before heat treatment are formed by subjecting the single crystal silicon ingot grown by the Czochralski method, for example, to processing such as chamfering of the outer periphery, lapping, etching, and double-sided mirror polishing, after being sliced in a wafer-like manner by an internal peripheral blade slicing machine or a wire saw.

Patent Literature 4 and 5 disclose techniques to specify the bevel angle of wafers and the inclination angle of the wafer support member, such as susceptor, to inhibit slips due to performing the RTA process.

Patent Literature 6 listed below discloses heat treatment tools that are capable of preventing not only slip but also the occurrence of damage to the wafer backside and chamfered portions by forming the support surface of the support member that supports the wafer backside during heat treatment to be convex.

### CITATION LIST

### Patent Literature

PTL 1: JP-A-2015-204326
PTL 2: JP-A-2022-050071
PTL 3: JP-A-2013-201314
PTL 4: JP-A-2007-036105
PTL 5: JP-A-2006-019625
PTL 6: JP-A-2006-005271

### SUMMARY OF INVENTION

### Technical Problem

As stated in PTL 1, the RTA process at a temperature of 1300° C. or more is preferable for the annihilation of defects on the surface and in the surface layer and the formation of BMD in the bulk layer of the semiconductor wafer. However, when the RTA process is performed, slip occurs due to the stresses caused by the temperature difference within the wafer plane and the own weight of the semiconductor wafer as the driving force. In particular, when the wafer support member is an edge ring supporting the semiconductor wafer from the backside outer periphery, slip tends to occur at the outer periphery due to the simultaneous stress due to the own weight of the wafer and the thermal stress due to the temperature difference between the semiconductor wafer and the wafer support member at the contacting position of the semiconductor wafer and the wafer support member.

In addition, as stated in PTL 2 and PTL 3, if the semiconductor wafers (especially, the wafer backside and the wafer backside bevel) have been mirror-polished before heat treatment, the welding-originated slip tends to occur because the contact area between the semiconductor wafer and the wafer support member increases during performing the RTA process.

Since the slip described above may cause the device to be defective, heat treatment to prevent slip is required.

Meanwhile, PTL 4 and 5 disclose techniques to specify the bevel angle of wafers and the inclination angle of the wafer support member to inhibit slip due to the performing the RTA process, and PTL 6 describes that the support surface of the wafer support member that supports the wafer backside during heat treatment is formed to be convex-curved. However, since the effect of heat dissipation in the wafer contact area (the wafer backside and the wafer backside bevel side) is not considered during cooling, there is room for further improvement in terms of inhibiting slips caused by thermal stress.

In addition to semiconductor wafers, there is also a need for a method to prevent slips caused by performing the RTA process in the process of manufacturing semiconductor devices from semiconductor wafers.

The present invention has been made in view of the above problems, and it is an object of the present invention to provide a method of manufacturing semiconductor wafers in which slips caused by the performing of the RTA process are inhibited. Another object of the present invention is to provide a method of manufacturing semiconductor devices to inhibit slips due to the performance of the RTA process.

### Solution to Problem

A method of manufacturing a semiconductor wafer, having a step for performing the RTA process, and performing the RTA process while the wafer is placed on a wafer support member having a support surface inclined downwardly toward the inside, the method includes a bevel-forming step in which the angle between the wafer backside and the wafer backside bevel is formed into an obtuse angle and the semiconductor wafer is machined so that the apex of the obtuse angle contacts the support surface during the RTA process, wherein, in the process of performing the RTA process, the angle θ1 of the angle between the wafer backside and the support surface formed at the contact position between the apex of the obtuse angle and the support surface, and the angle θ2 between the wafer backside bevel and the support surface are set to θ1≥5° and θ2≥5°, respectively, and further, the difference between the angles θ1 and θ2 is set to |θ1−θ2|≤5°.

With the method of manufacturing semiconductor wafers according to the present invention, slips caused at the contact area of the semiconductor wafer and the wafer support member can be reduced even when the RTA process is performed at a temperature of 1300° C. or higher, at which temperature the gettering performance to metal impurities is ensured.

In the method of manufacturing semiconductor wafers according to the present invention, the surface roughness of the semiconductor wafer at the above contacting position is desirably 5.0 nm≤Ra≤30.0 nm, and the angle θ3 between the wafer backside and the wafer backside bevel is desirably 157°≤θ3≤167°.

In the method of manufacturing semiconductor wafers according to the present invention, the RTA process is desirably performed under the conditions that the wafer is kept at the maximum temperature reached of 1300° C. or higher and 1350° C. or lower for a time duration of is or more and 60 s or less in an oxidizing atmosphere and is cooled down to 1000° C. ore less at a cooling rate of 50° C./s or more and 120° C./s ore less. Furthermore, in the method of manufacturing semiconductor wafers according to the present invention, the diameter of the semiconductor wafer subjected to the RTA process is desirably 300 mm or more. In addition, in the method of manufacturing semiconductor wafers according to the present invention, the difference between the angles θ1 and θ2 is set to |θ1−θ2|=0°.

A method of manufacturing a semiconductor device according to the present invention, having a step of performing the RTA process, and performing the RTA process while the wafer is placed on a wafer support member having a support surface that inclines downwardly toward the inside, wherein the semiconductor wafer is manufactured such that the angle between the wafer backside and the wafer backside bevel is formed into an obtuse angle and is processed so that the apex of the obtuse angle contacts the support surface during the RTA process, and wherein in the process of performing the RTA process, the angle θ1 of the angle between the wafer backside and the support surface formed at the contact position between the apex of the obtuse angle and the support surface, and the angle θ2 between the wafer backside and the support surface are set to θ1≥5° and θ2≥5°, respectively, and in addition, the difference between the angles θ1 and θ2 is set to |θ1−θ2|≤5°.

### Advantageous Effects of Invention

With the method of manufacturing a semiconductor wafer and a semiconductor device according to the present invention, slips caused by the RTA process are inhibited.

### BRIEF DESCRIPTION OF DRAWINGS

FIG. 1 is a cross-sectional view schematically illustrating the method of manufacturing a semiconductor wafer according to the present invention;

FIG. 2 is a schematical view of an example of a constitution of a rapid thermal process apparatus;

FIG. 3 shows an example of slip generation factors;

FIGS. 4A-4D shows an example of slip generation factors; and

FIG. 5 shows the results of the strain-area ratio measurements by SIRD for each silicon wafer produced by the methods of Example 1 and Comparative Examples 1-3.

### SOLUTION TO PROBLEM

Embodiments of the method of manufacturing a semiconductor wafer according to the present invention will be described in detail with reference to the drawings. However, the present invention is not limited by the embodiments.

### Method of Manufacturing

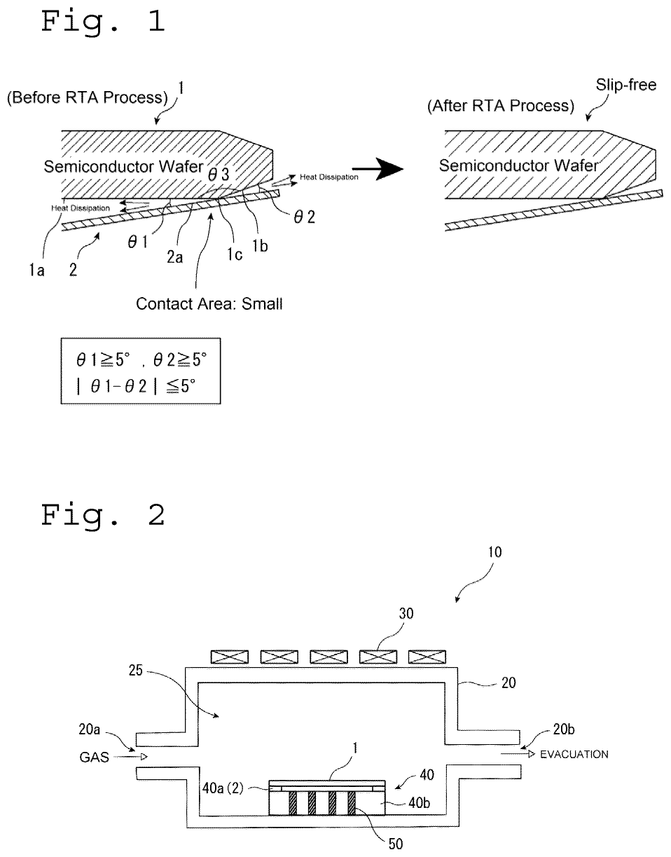

FIG. 1 is a cross-sectional view schematically illustrating the method of manufacturing a semiconductor wafer (Sometimes simply called “a wafer”) of this embodiment. The method of manufacturing a semiconductor wafer of the present embodiment includes a step of performing the RTA process, where the RTA process is performed while the semiconductor wafer 1 is placed on a wafer support member 2 having a support surface 2a that inclines downwardly toward the inside. Furthermore, the method of manufacturing a semiconductor wafer of the present embodiment includes a bevel-forming step in which the angle between the wafer backside 1a and the wafer backside bevel 1b is formed into an obtuse angle and the semiconductor wafer 1 is machined so that the apex 1c of the obtuse angle contacts the support surface 2a during the RTA process. In addition, when the RTA process is performed, the wafer 1 is produced such that the angle θ1 between the wafer backside 1a and the support surface 2a formed at the contact position with the support surface 2a and the angle θ2 between the wafer backside bevel 1b and the support surface 2a are set to θ1≥5° and θ2≥5°, respectively, and in addition, the difference between the angles θ1 and θ2 satisfy the relation |θ1−θ2|≤5°.

In the method of manufacturing a semiconductor wafer of the present embodiment, the RTA process is performed under the condition that the wafer is kept at the maximum temperature reached of 1250° C. or higher (preferably 1300° C. or higher and 1350° C. or lower) for a time duration of is or more and 60 s or less in an oxidizing atmosphere and is cooled down to 1000° C. or less at a cooling rate of 50° C./s or more and 120° C./s ore less. With this, the semiconductor wafer 1 having a satisfactory gettering capability against the metal impurities can be manufactured.

The present embodiment proposes the method of manufacturing a semiconductor wafer that allows for the reduction of slips caused at the contact area of the semiconductor wafer 1 and the wafer support member 2 can be reduced even when the RTA process is performed at a temperature of 1300° C. or higher, where the gettering performance against metal impurities is ensured.

### RTA Process

The RTA process in the step of manufacturing the semiconductor wafer 1 will be described. The rapid thermal process (RTP) apparatus 10 used in the present embodiment is provided with, for example, as shown in FIG. 2, a chamber (reaction tube) 20 having an atmosphere gas inlet 20a and an atmosphere gas outlet 20b, multiple lamps 30 disposed separately on the upper part of the chamber 20, and a wafer support 40 supporting the semiconductor wafer 1 in a reaction space 25 of the chamber 20.

The wafer support 40 is provided with an annular wafer support member 40a (corresponding to the wafer support member 2) which supports the outer peripheral part of the semiconductor wafer 1, a stage 40b which supports the wafer support member 40a. The wafer support 40 is provided with a rotation means (not shown) which rotates the semiconductor wafer 1 around its central shaft at a predetermined speed.

When the RTA process is performed on the semiconductor wafer 1 using the RTP apparatus 10 shown in FIG. 2, the semiconductor wafer 1 is introduced into the reaction space 25 through a wafer introduction opening (not shown) provided in the chamber 20 and is mounted on the wafer support member 40a. Then, an atmosphere gas is introduced through the atmosphere gas inlet 20a, and the wafer surface is irradiated with the lamp 30 while rotating with the rotation means.

The temperature control in the reaction space 25 of the RTP apparatus 10 is performed by measuring the temperatures of the lower portion of the semiconductor wafer 1 at the multiple points within the wafer plane in the radial direction of the wafer using multiple radiation thermometers 50 buried in the stage 40b, and controlling the multiple lamps 30 based on the measured temperature (individual ON-OFF control of each lamp or light intensity control of the emitted light).

### Details of the Manufacturing Method

The method of manufacturing the semiconductor wafer of the embodiment will be described in detail based on the drawings.

In the method of manufacturing the semiconductor wafer of the embodiment, after obtaining a semiconductor single crystal ingot grown by the Czochralski (CZ) method, the semiconductor single crystal ingot is sliced into a wafer shape (Slicing) by such as a wire saw. The sliced semiconductor wafers are beveled (Beveling). Then, the layer with bumps and recesses formed by slicing is removed to adjust to the desired flatness and surface roughness by the lapping process (Lapping) and grinding process (Grinding). Finally, the damaged layer damaged by the lapping process and the grinding process is removed by the etching process (Etching).

In the present embodiment, a semiconductor wafer 1 in which an angle between the wafer backside 1a and the wafer backside bevel 1b is obtuse is prepared following the above-mentioned manufacturing flow (Slicing→Beveling→Lapping→Grinding→Etching), as shown in FIG. 1. In this case, for example, a semiconductor wafer with a diameter of 300 mm or more is prepared. At the time the semiconductor wafer 1 is placed on the support surface 2a which is inclined downward toward the inside of the wafer, of the wafer support member 2, the semiconductor wafer 1 is processed such that the boundary portion (the apex 1c of the obtuse angle) between the wafer backside 1a and the wafer backside bevel 1b contacts the support surface 2a. Specifically, as shown in FIG. 1, the angle θ1 between the wafer backside 1a and the support surface 2a formed at the contact position, and the angle θ2 between the wafer backside bevel 1b and the support surface 2a are set to θ1≥5° and θ2≥5°, respectively, and further, the difference between the angles θ1 and θ2 is set to |θ1−θ2|≤5°.

The adjustments of the angle θ1 and the angle θ2 are performed by controlling the angle θ3 between the wafer backside 1a and the wafer backside bevel 1b when it is beveled, and by adjusting the angle of the support surface 2a of the wafer support member 2. In the method of manufacturing a semiconductor wafer of the present embodiment, after the RTA process is performed on the semiconductor wafer 1 prepared by the above manufacturing processes, the surface of the wafer is mirror polished.

By preparing the semiconductor wafer 1 as described above to perform the RTA process, slips caused by welding are inhibited because the contact area between the semiconductor wafer 1 and the wafer support member 2 is minimized (see FIG. 1). Furthermore, by specifying the angles θ1 and θ2 as described above, the difference in heat dissipation between the wafer backside 1a side and the wafer backside bevel 1b side is suppressed (see FIG. 1) at the contact position between the semiconductor wafer 1 and the wafer support member 2 is suppressed, and the thermal stress generated at the contact position between the semiconductor wafer 1 and the wafer support member 2 is inhibited, thereby slip caused by thermal stress is also minimized.

For example, when the RTA process is carried out on the semiconductor wafers that are mirror-polished after the etching process, the boundary portion of the wafer backside and the wafer backside bevel becomes a smooth surface, and the contact area between the semiconductor wafer and the wafer support member 2 tends to increase (see FIG. 3), whereby the slip caused by welding occurs in the RTA process at a temperature of 1300° C. or higher.

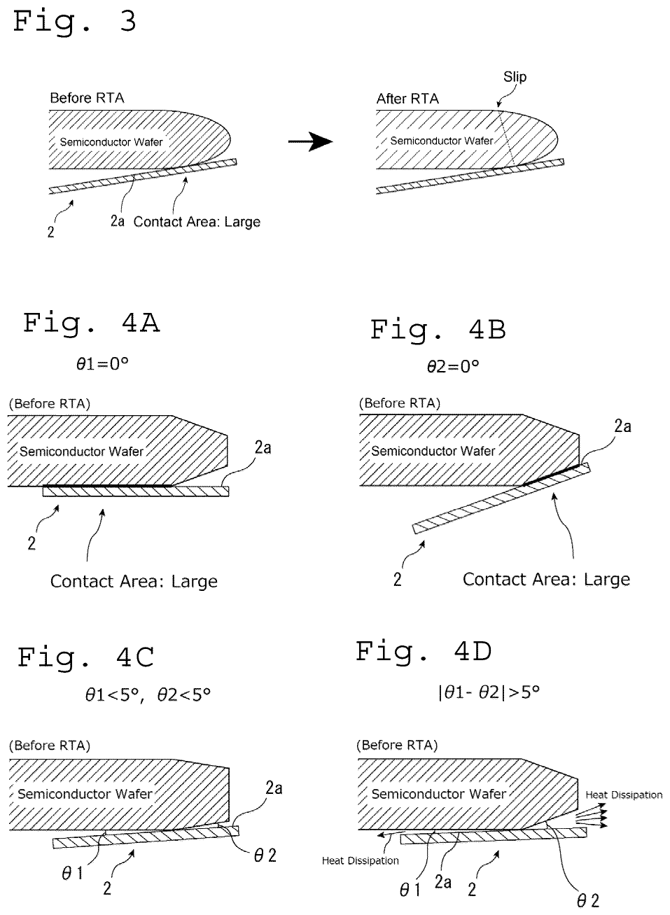

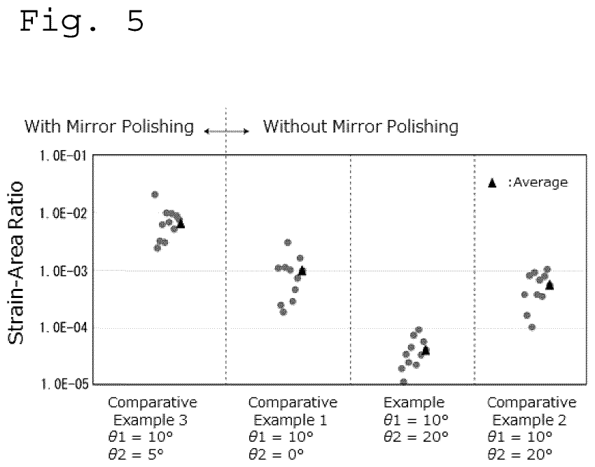

Further, when the angle θ1 is 0°, the wafer support member 2 and the wafer backside are in close contact (see FIG. 4A), and when the angle θ2 is 0°, the wafer support member 2 and the wafer backside bevel are in close contact (see FIG. 4B), the slip caused by welding occurs in the RTA process at 1300° C. or higher, for example.

If the angles θ1 and θ2 are too small, for example, less than 5 degrees, slip occurs due to thermal stress because the contact portion between the semiconductor wafer and the wafer support member 2 is difficult to dissipate during rapid cooling (see FIG. 4C).

If the difference between the angles θ1 and θ2 is too large, for example, more than 5 degrees in difference, slip due to thermal stress will occur because the difference in dissipation on the wafer backside side and the wafer backside bevel side (see FIG. 4D) occurs at the contact position between the semiconductor wafer and the wafer support member 2.

In other words, by setting the angles to θ1≥5° and θ2≥5° in the present embodiment, the space for dissipation at the time of rapid cooling is ensured while suppressing the contact area between the semiconductor wafer 1 and the wafer support member 2 is suppressed to a minimum. Furthermore, by setting the angle difference to |θ1−θ2≤5°, the difference in dissipation on the wafer backside 1a side and the wafer backside bevel 1b side at the contact portion is suppressed, thereby suppressing the slip originating from the contact portion at the time of rapid cooling.

In the present embodiment, in order to further reduce the slip due to the performing of the RTA process, the surface roughness of the semiconductor wafer 1 in the vicinity of the contact position of the semiconductor wafer 1 with the wafer support member 2 is preferably to be 5.0 nm≤Ra≤30.0 nm in the above-mentioned manufacturing process. As a result, the contact area between the semiconductor wafer and the wafer support member 2 is reduced, and the slip due to welding can be further inhibited. When Ra<5.0 nm, the wafer contact area between the semiconductor wafer and the wafer support member 2 increases, which is undesirable because the slip due to welding is likely to occur. In addition, when Ra>30.0 nm, the surface of the semiconductor wafer is too rough, resulting in variations in the wafer contact area, which is undesirable because the slip due to own weight stress is likely to occur.

In this embodiment, the angle θ3 of the angle between the wafer backside 1a and the wafer backside bevel 1b should be 157°≤θ3≤167°. This prevents chipping and cracking of the wafer end face during wafer transport during manufacturing, while reducing the contact area between the semiconductor wafer 1 and the wafer support member 2, thereby preventing slip caused by welding. If θ3<157°, chipping and cracking of the wafer backside during wafer transfer are more likely to occur, which is undesirable. If θ3>167°, chipping and cracking are more likely to occur on the outermost end face of the wafer during wafer transfer, which is undesirable.

In the method of manufacturing semiconductor devices of this embodiment, semiconductor wafers (semiconductor wafers 1 mentioned above) are used which have an angle between the wafer backside and the wafer backside bevel which is obtuse and which have been processed such that the apex of the obtuse angle comes into contact with the support surface 2a of the wafer support member 2 when the RTA process is performed. The conventional known method is used as a manufacturing process of semiconductor devices. In the step of performing the RTA process, the angle θ1 between the wafer backside and the support surface 2a and the angle θ2 between the wafer backside bevel and the support surface 2a at the contact position of the apex of the obtuse angle and the support surface 2a are θ1≥5° and θ2≥5°, respectively. In addition, the difference between the angle θ1 and the angle θ2 is set to be |θ1−θ2|≤5°. As a result, the contact area of the semiconductor wafer 1 and the wafer support member 2 can be set to a minimum, and also in the method of manufacturing semiconductor devices, slip due to welding can be inhibited. Furthermore, by specifying the angles θ1 and θ2 as described above, the difference in heat dissipation between the wafer backside 1a side and the wafer backside bevel 1b side is suppressed at the contact position between the semiconductor wafer 1 and the wafer support member 2 is suppressed, and the thermal stress generated at the contact position between the semiconductor wafer 1 and the wafer support member 2 is inhibited, thereby also minimizing the slip caused by the thermal stress.

Successively, the method of manufacturing a semiconductor wafer according to the present invention will be further described based on examples. The present invention is not limited by the examples below.

### EXAMPLE

The fabrication process described (Beveling→Lapping→Grinding→Etching) was performed on silicon wafers obtained by slicing a silicon single crystal ingot with an oxygen concentration of 1.0×10¹⁸/cm³ to obtain ten (10) first silicon wafers of 300 mm in diameter (corresponding to the semiconductor wafer 1 described above; see FIG. 1) such that Ra=20 nm and θ3=160°. In addition, using an RTP apparatus having a wafer support member with a support surface inclined 10° downwardly toward the inside, the first silicon wafer was placed such that θ1=10°, θ2=10°, and |θ1−θ2|=0° with respect to the support surface, and the following RTA process was performed to produce silicon wafers (see FIG. 1).

### RTA Process Condition

The RTA process was performed at a maximum temperature reached of 1350° C. for a holding time of 30 s in an oxidizing atmosphere under the cooling conditions down to 1000° C. at a cooling rate of 120° C./s.

### Comparative Example 1

The fabrication process described in Comparative Example (Beveling→Lapping→Grinding→Etching) was performed on silicon wafers obtained by slicing a silicon single crystal ingot having an oxygen concentration of 1.0×10¹⁸/cm³ to obtain ten (10) second silicon wafers of 300 mm in diameter (see FIG. 4B) such that Ra=20 nm and θ3=170°. In addition, using the same RTP apparatus as in Example 1, the second silicon wafer was placed such that θ1=10°, θ2=0°, and |θ1−θ2|=10° with respect to the support surface of the wafer support member, and the RTA process was performed to obtain silicon wafers (see FIG. 4B) under the same conditions as in Example.

### Comparative Example 2

The fabrication process described in Comparative Example 2 (Beveling→Lapping→Grinding→Etching) was performed on silicon wafers obtained by slicing a silicon single crystal ingot having an oxygen concentration of 1.0×10¹⁸/cm³ to obtain ten (10) third silicon wafers of 300 mm in diameter (see FIG. 4D) such that Ra=20 nm and θ3=150°. In addition, using the same RTP apparatus as in Example, the third silicon wafer was placed such that θ1=10°, θ2=20°, and |θ1−θ2|=10° with respect to the support surface of the wafer support member, and the RTA process was performed to obtain silicon wafers (see FIG. 4D) under the same conditions as in Example.

### Comparative Example 3

The conventional fabrication process (Beveling→Lapping→Grinding→Etching→Mirror Polishing) was performed on silicon wafers obtained by slicing a silicon single crystal ingot having an oxygen concentration of 1.0×10¹⁸/cm3 to obtain ten (10) fourth silicon wafers of 300 mm in diameter (Ra=5 nm, to the support surface of the wafer support member before mirror polishing, θ1=10°, θ2=5°, and |θ1−θ2|=5°, θ3=165°; see FIG. 3). In addition, using the same RTP apparatus as in Example, the fourth silicon wafer was placed on the support surface of the wafer support member, and the RTA process was performed to obtain silicon wafers under the same conditions as in Example (see FIG. 3).

### Evaluation Method

Silicon wafers prepared by the methods of the Example and the Comparative Examples 1 to 3 are measured with the scanning infrared depolarization method (SIRD) and evaluated the slip and the strain-area ratio. That is, the strain-area ratio was calculated and evaluated, where the strain-area ratio is defined as the ratio of the area in which the strain stress is increased by slip to the total area of the silicon wafer. For example, the larger the strain-area ratio, the worse the slip quality, and the smaller the strain-area ratio, the better the slip quality.

FIG. 5 shows the measurement results of the strain-area ratio evaluated by the SIRD method for silicon wafers fabricated by the manufacturing method of Example and Comparative Examples 1 to 3. The silicon wafer fabricated by Comparative Example 1 has an average strain-area ratio of 9.7×10⁻⁴ and slips occurred due to welding with the wafer support member. The silicon wafer fabricated by Comparative Example 2 has an average strain-area ratio of 5.5×10⁻⁴ and slips due to thermal stress. The silicon wafer fabricated by Comparative Example 3 has the largest strain-area ratio of 7.5×10⁻³, and both slips due to welding with the wafer support member 2 and slips occurred due to thermal stress.

Meanwhile, it is found that the silicon wafer corresponding to the semiconductor wafer 1 fabricated by the method of Example has the smallest strain-area ratio of 4.1×10⁻⁵ and slip is best suppressed. It is further confirmed that the strain-area ratio at the outer periphery is reduced by 99% compared to the silicon wafer of Comparative Example 3.

### REFERENCE SIGNS LIST

1 semiconductor wafer
1a wafer backside
1b wafer backside bevel
1c apex
2 wafer support member
2a support surface
10 RTP apparatus
20 chamber (reaction tube)
20a atmosphere gas inlet
20b atmosphere gas outlet
25 reaction space
30 lamp
40 wafer support
40a wafer support member
40b stage
50 radiation thermometer

1. A method of manufacturing a semiconductor wafer comprising a process for performing an RTA process and performing the RTA process while the wafer is placed on a wafer support member having a support surface inclined downwardly toward the inside,
comprising:
a bevel forming step in which the angle between a wafer backside and a wafer backside bevel is formed into an obtuse angle and the semiconductor wafer is processed so that an apex of the obtuse angle contacts the support surface during the RTA process,
wherein, in the process of performing the RTA process, an angle θ1 of the angle between the wafer backside and the support surface formed at a contact position between the apex of the obtuse angle and the support surface, and an angle θ2 between the wafer backside bevel and the support surface are set to θ1≥5° and θ2≥5°, respectively, and further, the difference between the angles θ1 and θ2 is set to |θ1−θ2|≤5°.

2. The method of manufacturing the semiconductor wafer in claim 1,
wherein the surface roughness of the semiconductor wafer at the above contacting position is 5.0 nm≤Ra≤30.0 nm in the bevel forming step.

3. The method of manufacturing the semiconductor wafer in claim 1,
wherein the angle θ3 between the wafer backside and the wafer backside bevel is 157°≤θ3≤167° in the bevel forming step.

4. The method of manufacturing the semiconductor wafer in claim 1,
wherein the RTA process is performed under the conditions that the wafer is kept at the maximum temperature reached of 1300° C. or higher and 1350° C. or lower for a duration time of is or more and 60 s or less in an oxidizing atmosphere and is cooled down to 1000° C. or less at a cooling rate of 50° C./s or more and 120° C./s ore less.

5. The method of manufacturing the semiconductor wafer in claim 1,
wherein the diameter of the semiconductor wafer subjected to the RTA process is 300 mm or more.

6. The method of manufacturing the semiconductor wafer in claim 1,
wherein the difference between the angles θ1 and θ2 is set to |θ1−θ2|=0°.

7. A method of manufacturing semiconductor devices comprising a process for performing the RTA process, and performing the RTA process while the wafer is placed on the wafer support member having the support surface inclined downwardly toward the inside,
wherein the semiconductor wafer is manufactured such that the angle between the wafer backside and the backside bevel is formed into an obtuse angle and the apex of the obtuse contacts the support surface during the RTA process, and wherein in the step of performing the RTA, the angle θ1 between the wafer backside and the support surface formed at the contact position between the apex of the obtuse angle and the support surface, and the angle θ2 between the backside bevel and the support surface are set to θ1≥5° and θ2≥5°, respectively, and further the difference between the angles θ1 and θ2 is set to |θ1−θ2|55°.
